(19) United States
(12) Patent Application Publication
(10) Pub. No.: US 2016/0347064 A1
(43) Pub. Date: Dec. 1, 2016

(54) LIQUID EJECTION HEAD AND METHOD OF PROCESSING SILICON SUBSTRATE

(71) Applicant: CANON KABUSHIKI KAISHA, Tokyo (JP)

(72) Inventors: Keisuke Kishimoto, Yokohama-shi (JP); Taichi Yonemoto, Isehara-shi (JP)

(21) Appl. No.: 15/138,421

(22) Filed: Apr. 26, 2016

(30) Foreign Application Priority Data
May 27, 2015 (JP) 2015-107163

(51) Int. Cl. B41J 2/16; H01L 21/268; H01L 21/311; H01L 21/306; H01L 21/308

(52) U.S. Cl. CPC B41J 2/162; H01L 21/30604; H01L 21/3086; H01L 21/31111; H01L 21/268; B41J 2/1629; B41J 2/1634

(57) ABSTRACT

Provided is a liquid ejection head, including: a substrate including a supply path passing through the substrate from a first surface of the substrate to a second surface thereof opposite to the first surface; and a member bonded to the second surface of the substrate via an adhesive, in which an inner wall of the supply path has a portion substantially in parallel with the second surface.

### BACKGROUND OF THE INVENTION

Field of the Invention

The present invention relates to a liquid ejection head and a method of processing a silicon substrate.

Description of the Related Art

As an ink jet recording head configured to eject ink that is a liquid, an ink jet recording head of a type that ejects ink toward above an energy generating element configured to generate ink ejection energy (hereinafter referred to as a side shooter type head) is known. A side shooter type head employs a method in which an ink supply path that is a through hole is formed in a silicon substrate having the energy generating element formed thereon, and ink is supplied from a side opposite to a surface having the energy generating element formed thereon through the ink supply path. In this method, from the viewpoint of downsizing the side shooter type head, it is required to reduce an interval between ink supply paths.

### SUMMARY OF THE INVENTION

According to one embodiment of the present invention, there is provided a liquid ejection head, including: a substrate including a supply path passing through the substrate from a first surface of the substrate to a second surface thereof opposite to the first surface; and a member bonded to the second surface of the substrate via an adhesive, in which an inner wall of the supply path has a portion substantially in parallel with the second surface.

According to another embodiment of the present invention, there is provided a method of processing a silicon substrate, including, in the following order, the steps of: (a) forming an etching mask layer on a second surface of a silicon substrate, the silicon substrate having a (100) crystal plane and having a first surface and the second surface opposite to the first surface; (b) forming a plurality of blind holes from the second surface side of the silicon substrate; (c) performing crystal anisotropic etching from the second surface side of the silicon substrate using an etchant to join the plurality of blind holes together; (d) removing a part of a SiO₂ layer formed on the second surface of the silicon substrate; and (e) performing crystal anisotropic etching from the second surface side of the silicon substrate using an etchant to form a through hole.

Further features of the present invention will become apparent from the following description of exemplary embodiments with reference to the attached drawings.

### BRIEF DESCRIPTION OF THE DRAWINGS

FIG. 1 is a sectional view for illustrating an exemplary substrate for a liquid ejection head according to the present invention.

FIG. 2A, FIG. 2B, FIG. 2C, FIG. 2D and FIG. 2E are sectional views for illustrating a method of processing a silicon substrate according to a first embodiment (Example 1) of the present invention.

FIG. 3A, FIG. 3B, FIG. 3C, FIG. 3D and FIG. 3E are sectional views for illustrating a method of processing a silicon substrate according to a second embodiment (Example 2) of the present invention.

FIG. 4A, FIG. 4B, FIG. 4C and FIG. 4D are sectional views for illustrating a method of processing a silicon substrate according to Comparative Example 1.

### DESCRIPTION OF THE EMBODIMENTS

Preferred embodiments of the present invention will now be described in detail in accordance with the accompanying drawings.

In Japanese Patent Application Laid-Open No. 2007-237515, there is described employing, in a method of manufacturing a substrate for a liquid ejection head, a method of performing anisotropic etching after a blind hole is formed in the substrate using laser light. However, the through hole formed by this method has a sectional shape that laterally expands in the middle. Therefore, an interval between the through holes cannot be reduced, resulting in a limitation on reducing a width dimension of the liquid ejection head.

Meanwhile, an ink jet recording head substrate is mounted in the following method. An adhesive that is both UV-curable and thermocurable is transferred or applied to a support member. After the ink jet recording head substrate is pressed against the support member, ultraviolet light is radiated to a portion of the adhesive that is squeezed out of an outer peripheral portion of the ink jet recording head substrate to temporarily fix the ink jet recording head substrate. At this time, the remaining portion of the adhesive that is transferred between the ink jet recording head substrate and the support member is not irradiated with the ultraviolet light, and is thus still in an uncured state. Therefore, the adhesive is completely cured in a thermocuring step. However, in this method, when the ink jet recording head substrate is pressed, the adhesive may be squeezed out into a supply path that is a through hole, and enter the supply path. Entrance of the adhesive in the supply path lowers a defoaming property when a liquid, such as ink, flows therethrough.

As an ink jet recording head configured to prevent a squeezed out adhesive from entering the supply path, structures and manufacturing methods disclosed in Japanese Patent Application Laid-Open No. H11-348282 and Japanese Patent Application Laid-Open No. 2001-162802 are known. In these structures, through formation of an additional adhesive accumulating region in the vicinity of the supply path, the adhesive is prevented from entering the supply path. However, the structure cannot completely prevent the adhesive from entering the supply path. Since the ink jet recording head substrate is required to be in parallel with the support member, it is required to press the substrate. Because of the pressing, the adhesive is not sufficiently prevented from being squeezed out even if the adhesive accumulating region is formed, and the adhesive is thus squeezed out into the supply path.

Incidentally, for the purpose of reducing time necessary for etching, a method of removing a part of the silicon substrate to reduce time necessary for anisotropic etching is effective, as is described in Japanese Patent Application Laid-Open No. 2007-237515. As a part of the silicon substrate is removed to a deeper extent, the amount of the anisotropic etching can be reduced more, which can inhibit lateral expansion of the supply path. As a result, the ink jet recording head can be downsized and the time necessary for the etching can be reduced more effectively. However, if etching rates of the anisotropic etching are not controlled for the respective surface orientations, the width of the supply path increases depending on the anisotropic etching time. Therefore, the amount of the removed silicon is increased and the production efficiency is lowered.

As described above, although it is required to reduce the width dimension of the liquid ejection head, it is difficult to attain both of the reduction in interval between supply paths and the prevention of the adhesive from being squeezed out into the supply path. It is an object of the present invention to provide a liquid ejection head having a small interval between supply paths and having a satisfactory defoaming property.

### Liquid Ejection Head

A liquid ejection head according to the present invention includes: a substrate including a supply path passing through the substrate from a first surface of the substrate to a second surface thereof opposite to the first surface; and a member bonded to the second surface of the substrate via an adhesive. An inner wall of the supply path has a portion substantially in parallel with the second surface. The portion substantially in parallel with the second surface functions as a region for preventing the adhesive from being squeezed out. Therefore, even when the adhesive enters the supply path when the substrate and the member are bonded together, the adhesive stays on the portion that is substantially in parallel with the second surface. Thus, the adhesive does not go beyond the portion, and does not enter deeper into the supply path. Incidentally, when a liquid is supplied or ejected, an air bubble may be trapped in the supply path, and repeated liquid supply and liquid ejection therein makes the air bubble grow. The air bubble can be allowed to escape from the liquid supply side of the supply path. According to the present invention, the adhesive is not squeezed out from the portion that is substantially in parallel with the second surface, and thus, the air bubble can be easily allowed to escape from the liquid supply side. Thus, a satisfactory defoaming property is attained when the liquid ejection head is manufactured. Further, in this configuration, an interval between supply paths can be small. A liquid ejection head according to the present invention is described in detail below.

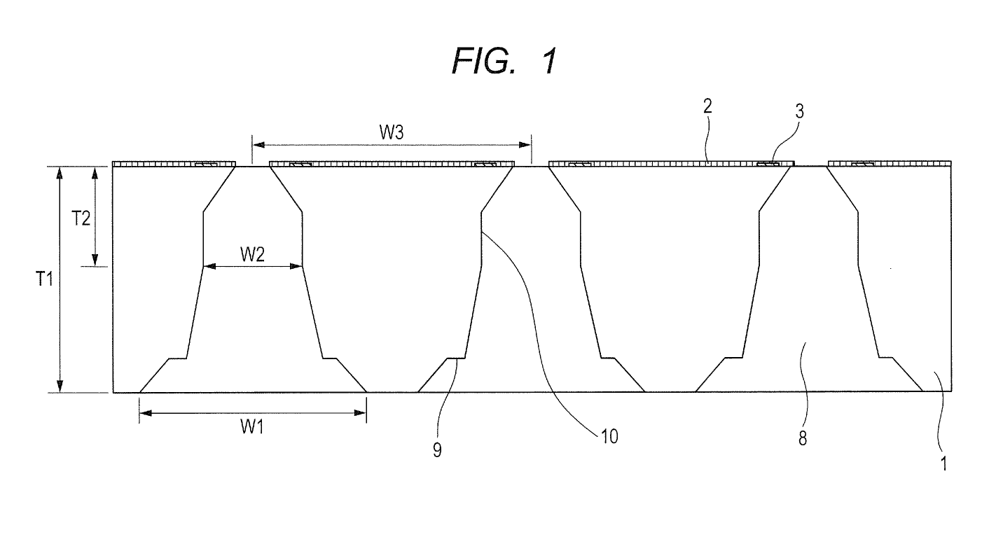

FIG. 1 is an illustration of an exemplary substrate for a liquid ejection head according to the present invention. A plurality of energy generating elements 3 are arranged on the first surface of a substrate 1. Further, an etching stop layer 2 is formed on a first surface of the substrate 1. A plurality of supply paths 8 that pass through the substrate 1 and that are configured to supply a liquid therethrough are formed in the substrate 1. The inner wall of the supply path 8 illustrated in FIG. 1 is formed of five surfaces. A portion 9 substantially in parallel with a second surface of the substrate 1 is formed as a part of an inner wall of the supply path 8. Note that, the expression “substantially in parallel” as used herein means a state of being in a range of ±5° relative to a reference surface. It is preferred that the portion 9 substantially in parallel with the second surface exist in a region that is located beyond ½ of the thickness of the substrate 1 from the first surface of the substrate 1 in a substrate thickness direction.

From the viewpoint of downsizing the liquid ejection head, it is preferred that an interval W3 between the supply paths 8 be 1 mm or less, and it is more preferred that the interval W3 be 0.9 mm or less. Note that, the interval W3 between the supply paths 8 means a distance between the centers of the supply paths 8. Further, the interval W3 between the supply paths 8 means an interval between supply paths that are the closest to each other.

A portion 10 substantially perpendicular to the second surface is formed as a part of the inner wall of the supply path 8 illustrated in FIG. 1. Note that, the expression “substantially perpendicular” as used herein means a state of being in a range of ±5° relative to a surface perpendicular to a reference surface. It is preferred that an opening width W2 of the portion 10 substantially perpendicular to the second surface of the supply path 8 be ½ or less of an opening width W1 of the supply path 8 on the second surface, and it is more preferred that the opening width W2 be ⅖ or less of the opening width W1. Further, it is preferred that the portion 10 substantially perpendicular to the second surface exist in a region that is located within ½ of the thickness of the substrate 1 from the first surface of the substrate 1 in the substrate thickness direction, and it is more preferred that the portion 10 exist in a region that is located within ⅖ of the thickness of the substrate 1 from the first surface of the substrate 1 in the substrate thickness direction. In other words, in FIG. 1, it is preferred that T2/T1 be ½ or less, and it is more preferred that T2/T1 be ⅖ or less. The portion 10 substantially perpendicular to the second surface formed as a part of the inner wall of the supply path 8 that satisfies these requirements improves the defoaming property.

The liquid ejection head according to the present invention includes the substrate, and a member bonded to the second surface of the substrate via the adhesive. As the member, a support member can be used. As the adhesive, for example, an epoxy adhesive containing an epoxy resin can be used. An adhesive of one kind may be used alone, or adhesives of two or more kinds may be used in combination.

A configuration on the first surface side of the substrate for the liquid ejection head according to the present invention can be a publicly known configuration. For example, a flow path member having ejection orifices formed therein, for forming a flow path of the liquid may be formed on the first surface of the substrate. Energy is given by an energy generating element to the liquid that is supplied from the second surface side of the substrate through the supply path, and the liquid is ejected as a liquid droplet from an ejection orifice through the flow path in the flow path member.

The liquid ejection head according to the present invention can be suitably used as an ink jet recording head configured to produce a record through ejecting ink on a recording medium, a head for manufacturing a color filter, or the like. Further, the present invention can be applied to, other than an ink jet recording head, a liquid ejection head for manufacturing a biochip or for printing an electronic circuit as well.

### Method of Processing Silicon Substrate

A method of processing a silicon substrate according to the present invention includes the following steps (a) to (e) in the following order: the step (a) of forming an etching mask layer on a second surface of a silicon substrate, the silicon substrate having a (100) crystal plane and having a first surface and the second surface opposite to the first surface; the step (b) of forming a plurality of blind holes from the second surface side of the silicon substrate; the step (c) of performing crystal anisotropic etching from the second surface side of the silicon substrate using an etchant to join the plurality of blind holes together; the step (d) of removing a part of a SiO₂ layer formed on the second surface of the silicon substrate; and the step (e) of performing crystal anisotropic etching from the second surface side of the silicon substrate using an etchant to form a through hole.

According to the method of processing a silicon substrate according to the present invention, the substrate for the liquid ejection head according to the present invention can be suitably manufactured. Note that, the method of processing a silicon substrate according to the present invention can be applied to, other than manufacture of the substrate for the liquid ejection head according to the present invention, formation of a through hole in a structure including a silicon substrate as well. Embodiments of the method of processing a silicon substrate according to the present invention are described below, but the present invention is not limited to these embodiments.

### First Embodiment

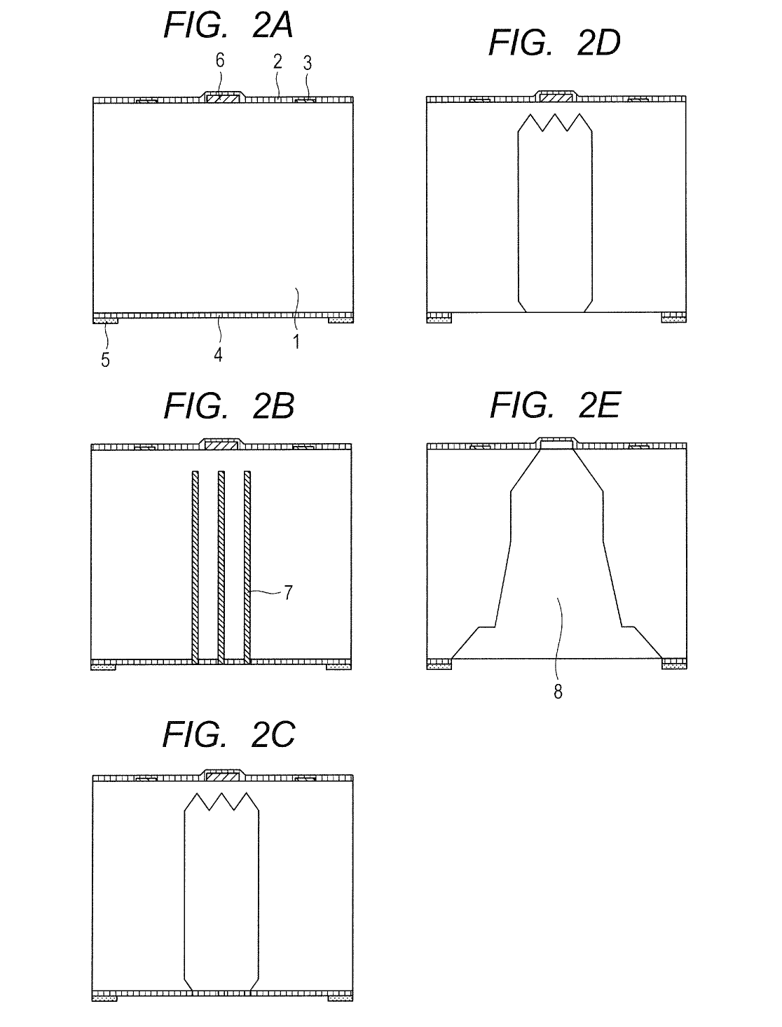

In a first embodiment of the present invention, a silicon substrate is processed in steps illustrated in FIG. 2A to FIG. 2E. Note that, in this embodiment, description is given of a single silicon substrate 1 serving as a part of a wafer, but, in practice, similar processing is performed per a wafer.

First, as illustrated in FIG. 2A, the silicon substrate 1 having the etching stop layer 2, the energy generating element 3, and a sacrifice layer 6 formed on the first surface thereof and having a (100) crystal plane is prepared. The silicon substrate 1 can have a thickness of from 700 μm to 750 μm. The energy generating element 3 is an element configured to generate energy for ejecting a liquid, and as the energy generating element 3, for example, an electrothermal converting element formed of TaN, TaSiN, or the like can be used. A control signal input electrode (not shown) configured to drive the energy generating element 3 is electrically connected to the energy generating element 3. The etching stop layer 2 is also referred to as a passivation layer. The etching stop layer 2 functions as a protective layer for the energy generating element 3, and is formed of a material resistant to crystal anisotropic etching. Further, the etching stop layer 2 functions as a partition when the first surface of the silicon substrate 1 has structures, such as the energy generating element 3 and the flow path member, formed thereon. Formation of the sacrifice layer 6 is effective when a region in which the supply path 8 is to be formed is required to be defined with accuracy. It is only necessary that the sacrifice layer 6 and the etching stop layer 2 are, when each layer is used solely or when the two layers are used in combination, formed on the silicon substrate 1 before the crystal anisotropic etching is performed. The sacrifice layer 6 and the etching stop layer 2 are formed at any timing and with any order before the crystal anisotropic etching, and can be formed by a publicly known method. Further, although not illustrated in FIG. 2A, a resin layer or the like may be formed on the first surface of the silicon substrate 1, so as to serve as the flow path member having a liquid flow path.

A SiO₂ layer 4 is formed on the second surface of the silicon substrate 1. An etching mask layer 5 having an opening formed therein is formed on the SiO₂ layer 4. The opening is to be a region from which the crystal anisotropic etching starts. The etching mask layer 5 can be formed by, for example, applying a polyamide resin such as a polyether amide resin. The opening can be formed by patterning using photolithography. It is preferred that the opening have a width of from 0.6 mm to 0.9 mm. The opening is formed in advance in a region of the etching mask layer 5 in which blind holes 7 to be described below are to be formed, as illustrated in FIG. 2A. With this, removal of the SiO₂ layer 4 is facilitated, which is described below with reference to FIG. 2D.

Next, as illustrated in FIG. 2B, the plurality of blind holes 7 are formed from the second surface side of the silicon substrate 1. A flow path member or the like may be formed on the first surface side of the silicon substrate 1, and thus, it is preferred that the blind holes 7 be formed by radiation of laser light from the second surface side of the silicon substrate 1. As the laser light, for example, a fundamental wave (wavelength of 1,064 nm), a second harmonic wave (wavelength of 532 nm), a third harmonic wave (wavelength of 355 nm), or the like of a YAG laser can be used. Note that, it is only necessary that the laser light has a wavelength with which a hole can be formed in silicon that forms the silicon substrate 1, and the wavelength is not specifically limited. For example, when a fundamental wave (wavelength of 1,064 nm) of a YAG laser is used, the blind holes 7 may be formed in the silicon by thermal processing using the laser light. Alternatively, the blind holes 7 may be formed by ablation using laser light, that is, so-called laser ablation. Further, the output and the frequency of the laser light can be set at appropriate values.

It is preferred that the blind holes 7 have a diameter of from 5 μm to 100 μm. When the blind holes 7 have a diameter of 5 μm or more, an etchant can enter the blind holes 7 more easily later in the crystal anisotropic etching. When the blind holes 7 have a diameter of 100 μm or less, the blind holes 7 can be formed in a relatively short time.

Further, it is preferred that the blind holes 7 be formed to a depth of 10 μm or more and 125 μm or less from the first surface of the silicon substrate 1. It is more preferred that the blind holes 7 be formed to a depth of 30 μm or more and 100 μm or less. For example, when the silicon substrate 1 used has a thickness of 725 μm, it is preferred that the blind holes 7 have a depth of 600 μm or more and 715 μm or less, and it is more preferred that the blind holes 7 have a depth of 625 μm or more and 695 μm or less. Formation of the blind holes 7 to a depth of 125 μm or less from the first surface of the silicon substrate 1 can reduce time taken for the crystal anisotropic etching later, and can further reduce the width of the through hole 8 (supply path 8). Further, formation of the blind holes 7 to a depth of 10 μm or more from the first surface of the silicon substrate 1 prevents heat generated by the laser or the like from being easily transferred to a structure such as a flow path member formed on the first surface of the silicon substrate 1, which can inhibit deformation and the like thereof.

Further, from the viewpoint of reducing time taken for etching the second surface, it is preferred that the blind holes 7 be formed in two or more lines that are symmetrical with respect to a center line in a longitudinal direction of the region in which the blind holes 7 are to be formed, and it is more preferred that the blind holes 7 be formed in three or more lines. In this embodiment, the blind holes 7 are formed in three lines that are symmetrical with respect to the center line in the longitudinal direction of the region in which the blind holes 7 are to be formed. Note that, when the number of the lines of the blind holes 7 is an odd number, the blind holes 7 are formed so that the line of the blind hole 7 that is in the middle is on the center line in the longitudinal direction of the region.

Further, it is preferred that the blind holes 7 be formed so that an interval between the blind holes 7 be 25 μm or more and 115 μm or less, and it is more preferred that the blind holes 7 be formed so that the interval between the blind holes 7 be 40 μm or more and 80 μm or less. As used herein, the interval between the blind holes 7 means an interval between blind holes 7 that are the closest to each other. When the interval between the blind holes 7 is 25 μm or more and 115 μm or less, it is easier to form the blind holes 7 so as to have a desired depth, and the through holes 8 (supply paths 8) are less liable to be joined together. The interval between the blind holes 7 can be, for example, 25 μm or more and 115 μm or less in a short direction and in the longitudinal direction of the silicon substrate 1. It is preferred that the blind holes 7 be formed in symmetrical two or more lines so that the interval between the blind holes 7 be 25 μm to 115 μm in the short direction and in the longitudinal direction of the silicon substrate 1.

Next, as illustrated in FIG. 2C, crystal anisotropic etching is performed using an etchant from the second surface side of the silicon substrate 1 to join the blind holes 7 together. It is preferred that, as the etchant, from the viewpoint of easy etching, an etchant containing tetramethylammonium hydroxide (TMAH) or potassium hydroxide be used. Further, the etchant can contain an additive such as polyoxyethylene glycol or a polyoxyethylene derivative. In the crystal anisotropic etching, the etching starts from the entire inner walls in the plurality of blind holes 7. The crystal anisotropic etching is stopped when the blind holes 7 are joined together by the crystal anisotropic etching. Note that, a (111) plane is formed from a tip of a blind hole 7 located on an outer peripheral side of the plurality of blind holes 7. At that time, through usage of an etchant having a (100) plane etching rate that is higher than a (110) plane etching rate, time taken until the blind holes are joined together becomes longer, but the blind holes 7 can be joined together.

Then, as illustrated in FIG. 2D, a part of the SiO₂ layer 4 formed on the second surface of the silicon substrate 1 is removed. Specifically, a portion of the SiO₂ layer 4 that is formed in the opening in the etching mask layer 5 is removed. From the viewpoint of mass production, it is preferred that the SiO₂ layer 4 be removed by dry etching or wet etching. Exemplary dry etching includes plasma etching using a fluorine-based gas. Exemplary wet etching includes etching using buffered hydrofluoric acid, hydrofluoric acid, or the like.

Then, as illustrated in FIG. 2E, crystal anisotropic etching is performed using an etchant from the second surface side of the silicon substrate 1 to form the through hole 8. As the etchant, an etchant similar to the etchant described above can be used. In the crystal anisotropic etching, the etching progresses toward the first surface side of the silicon substrate 1. At the same time, the etching progresses as well in the opening in the etching mask layer 5 after the SiO₂ layer 4 is removed therefrom. When the etching reaches the first surface of the silicon substrate 1, the etching ends. Note that, although not illustrated, by removing a part of the etching stop layer 2 that is formed in the opening of the through hole 8 in the first surface of the silicon substrate 1 by dry etching or the like, the through hole 8 can open to the first surface side of the silicon substrate 1. From the viewpoint of downsizing the liquid ejection head, it is preferred that an interval between the through holes 8 be 1 mm or less, and it is more preferred that the interval between the through holes 8 be 0.9 mm or less. Note that, the interval between the through holes 8 means a distance between the centers of the through holes 8. Further, the interval between the through holes 8 means an interval between through holes 8 that are the closest to each other.

### Second Embodiment

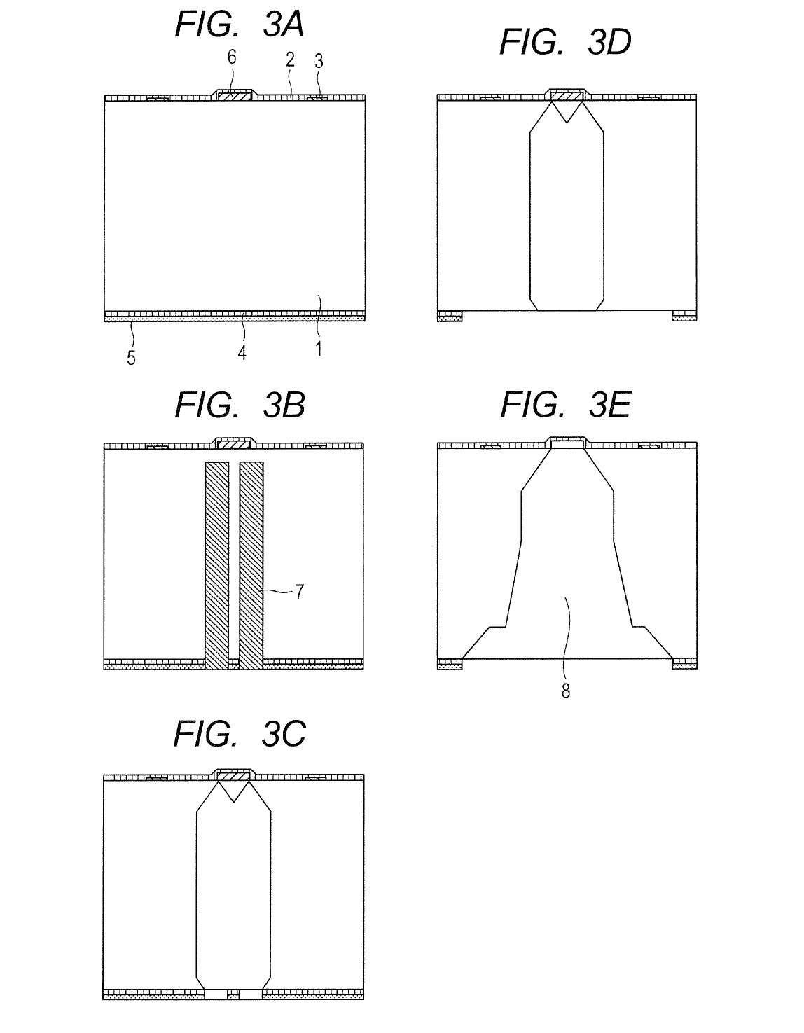

In a second embodiment of the present invention, the silicon substrate is processed in steps illustrated in FIG. 3A to FIG. 3E.

First, as illustrated in FIG. 3A, similarly to the first embodiment, the silicon substrate 1 having the etching stop layer 2, the energy generating element 3, and the sacrifice layer 6 formed on the first surface thereof and having the (100) crystal plane is prepared. Further, the etching mask layer 5 is formed on the SiO₂ layer 4 on the second surface of the silicon substrate 1 similarly to the first embodiment except that the opening is not formed.

Next, as illustrated in FIG. 3B, similarly to the first embodiment, the plurality of blind holes 7 are formed from the second surface side of the silicon substrate 1. Note that, according to this embodiment, the blind holes 7 are formed in two lines that are symmetrical with respect to the center line in the longitudinal direction of the region in which the blind holes 7 are to be formed.

Next, as illustrated in FIG. 3C, similarly to the first embodiment, crystal anisotropic etching is performed using an etchant from the second surface side of the silicon substrate 1 to join the blind holes 7 together.

Then, as illustrated in FIG. 3D, an opening is formed in the etching mask layer 5. The opening can be formed by, for example, patterning using photolithography. After that, similarly to the first embodiment, the SiO₂ layer 4 formed in the opening in the etching mask layer 5 is removed.

Then, as illustrated in FIG. 3E, similarly to the first embodiment, crystal anisotropic etching is performed using an etchant from the second surface side of the silicon substrate 1 to form the through hole 8.

Note that, in the two embodiments described above, a step of forming the through hole 8 (supply path 8) in the silicon substrate 1 is described. However, when a liquid ejection head is manufactured, it is preferred that, prior to the step performed in the embodiments described above, a step of forming a flow path forming member on the first surface of the silicon substrate 1 be performed.

### EXAMPLES

Now, specific embodiments of the present invention are described by way of Examples. However, the present invention is by no means limited to the following Examples.

### Example 1

The silicon substrate was processed in the steps illustrated in FIG. 2A to FIG. 2E to manufacture the liquid ejection head.

First, as illustrated in FIG. 2A, the silicon substrate 1 having the etching stop layer 2, the energy generating element 3, and the sacrifice layer 6 formed on the first surface thereof and having a (100) crystal plane was prepared. The silicon substrate 1 had a thickness of 725 μm. The SiO₂ layer 4 was formed on the second surface of the silicon substrate 1. A layer containing a polyether amide resin was formed on the SiO₂ layer 4, patterning was performed using photolithography, and the etching mask layer 5 having an opening therein was formed. The opening in the etching mask layer 5 had a width of 0.75 mm.

Next, as illustrated in FIG. 2B, the blind holes 7 were formed in the opening in the etching mask layer 5 using laser light. At this time, the blind holes 7 were formed in three lines that were symmetrical with respect to the center line in the longitudinal direction of the region in which the blind holes 7 were to be formed. The interval between the blind holes 7 was 60 μm in the longitudinal direction and in the short direction. Further, the blind holes 7 had a depth of 650 μm. In other words, the blind holes 7 were formed to a depth of 75 μm from the first surface of the silicon substrate 1. The blind holes 7 had a diameter of 20 μm.

Next, as illustrated in FIG. 2C, crystal anisotropic etching was performed from the second surface side of the silicon substrate 1 using a 22 mass % TMAH solution. As a result, the blind holes 7 were joined together.

Then, as illustrated in FIG. 2D, a portion of the SiO₂ layer 4 that was formed on the second surface of the silicon substrate 1 and in the opening in the etching mask layer 5 was removed using buffered hydrofluoric acid.

Then, as illustrated in FIG. 2E, crystal anisotropic etching was performed from the second surface side of the silicon substrate 1 using a 22 mass % TMAH solution. As a result, the plurality of through holes 8 (supply paths 8) that pass through the silicon substrate 1 were formed. An inner wall of the supply path 8 was formed of five surfaces, and had the portion substantially in parallel with the second surface and the portion substantially perpendicular to the second surface. An opening width of the portion substantially perpendicular to the second surface of the supply path 8 was 0.3 mm, which was ½ or less of an opening width of the supply path 8 on the second surface. Further, the portion substantially perpendicular to the second surface existed in a region that was located within ⅖ of the thickness of the substrate from the first surface of the silicon substrate 1 in the substrate thickness direction. Further, the interval between the supply paths 8 was 0.85 mm.

After that, a thermocurable epoxy adhesive was used to bond together the support member and the second surface of the silicon substrate 1. At this time, the adhesive that was squeezed out into the supply path 8 stayed on the portion substantially in parallel with the second surface of the inner wall of the supply path 8, and thus, did not reach the portion substantially perpendicular to the second surface. Therefore, when the liquid ejection head was manufactured and a liquid was caused to flow therethrough, the defoaming property was satisfactory.

### Example 2

The silicon substrate was processed in the steps illustrated in FIG. 3A to FIG. 3E to manufacture the liquid ejection head.

First, as illustrated in FIG. 3A, the silicon substrate 1 having the etching stop layer 2, the energy generating element 3, and the sacrifice layer 6 formed on the first surface thereof and having a (100) crystal plane was prepared. The silicon substrate 1 had a thickness of 725 μm. The SiO₂ layer 4 was formed on the second surface of the silicon substrate 1. The etching mask layer 5 containing a polyether amide resin was formed on the SiO₂ layer 4.

Next, as illustrated in FIG. 3B, the blind holes 7 were formed from the etching mask layer 5 side using laser light. At this time, the blind holes 7 were formed in two lines that were symmetrical with respect to the center line in the longitudinal direction of the region in which the blind holes 7 were to be formed. The interval between the blind holes 7 was 90 μm in the longitudinal direction and in the short direction. Further, the blind holes 7 had a depth of 680 μm. In other words, the blind holes 7 were formed to a depth of 45 μm from the first surface of the silicon substrate 1. The blind holes 7 had a diameter of 75 μm.

Next, as illustrated in FIG. 3C, crystal anisotropic etching was performed from the second surface side of the silicon substrate 1 using a 22 mass % TMAH solution. As a result, the blind holes 7 were joined together.

Then, as illustrated in FIG. 3D, patterning was performed using photolithography to form an opening in the etching mask layer 5. Further, a portion of the SiO₂ layer 4 that was formed on the second surface of the silicon substrate 1 and in the opening in the etching mask layer 5 was removed using buffered hydrofluoric acid.

Then, as illustrated in FIG. 3E, crystal anisotropic etching was performed from the second surface side of the silicon substrate 1 using a 22 mass % TMAH solution. As a result, the plurality of through holes 8 (supply paths 8) that pass through the silicon substrate 1 were formed. An inner wall of the supply path 8 was formed of five surfaces, and had the portion substantially in parallel with the second surface and the portion substantially perpendicular to the second surface. An opening width of the portion substantially perpendicular to the second surface of the supply path 8 was 0.35 mm, which was ½ or less of an opening width of the supply path 8 on the second surface. Further, the portion substantially perpendicular to the second surface existed in a region that was located within ½ of the thickness of the substrate from the first surface of the silicon substrate 1 in the substrate thickness direction. Further, the interval between the supply paths 8 was 0.9 mm.

After that, a thermocurable epoxy adhesive was used to bond together the support member and the second surface of the silicon substrate 1. At this time, the adhesive that was squeezed out into the supply path 8 stayed on the portion substantially in parallel with the second surface of the inner wall of the supply path 8, and thus, did not reach the portion substantially perpendicular to the second surface. Therefore, when the liquid ejection head was manufactured and a liquid was caused to flow therethrough, the defoaming property was satisfactory.

### Comparative Example 1

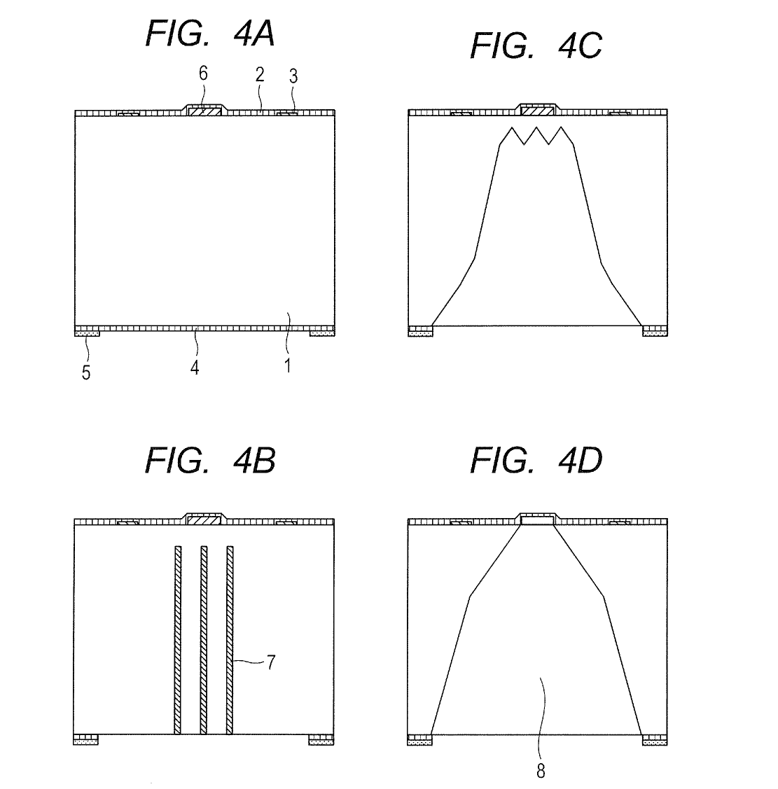

The silicon substrate was processed in the steps illustrated in FIG. 4A to FIG. 4D to manufacture the liquid ejection head. Note that, the step illustrated in FIG. 4A was performed in the same manner as the step illustrated in FIG. 2A in Example 1.

As illustrated in FIG. 4B, a portion of the SiO₂ layer 4 that was formed on the second surface of the silicon substrate 1 and in the opening in the etching mask layer 5 was removed using buffered hydrofluoric acid. After that, the blind holes 7 were formed in the opening in the etching mask layer 5 using laser light. At this time, the blind holes 7 were formed in three lines that were symmetrical with respect to the center line in the longitudinal direction of the region in which the blind holes 7 were to be formed. The interval between the blind holes 7 was 60 μm in the longitudinal direction and in the short direction. Further, the blind holes 7 had a depth of 650 μm. In other words, the blind holes 7 were formed to a depth of 75 μm from the first surface of the silicon substrate 1. The blind holes 7 had a diameter of 20 μm.

Next, as illustrated in FIG. 4C and FIG. 4D, crystal anisotropic etching was performed from the second surface side of the silicon substrate 1 using a 22 mass % TMAH solution. As a result, the blind holes 7 were joined together (FIG. 4C), and after that, the plurality of through holes 8 (supply paths 8) that pass though the silicon substrate 1 were formed (FIG. 4D). The inner wall of the supply path 8 was formed of two surfaces, and did not have a portion substantially in parallel with the second surface. The interval between the supply paths 8 was 1 mm. Further, the supply path 8 had a sectional shape that laterally expanded in the middle as illustrated in FIG. 4D. It is thought that, in the crystal anisotropic etching, the portion of the SiO₂ layer 4 that was formed in the opening in the etching mask layer 5 was removed, and thus, a contact time between the etchant and the silicon on the second surface side was long, with the result that the sectional shape of the supply path 8 laterally expanded to a large extent by the etching.

After that, a thermocurable epoxy adhesive was used to bond together the support member and the second surface of the silicon substrate 1. At this time, the adhesive that was squeezed out into the supply path 8 entered deep into the supply path 8. Therefore, when the liquid ejection head was manufactured and a liquid was caused to flow therethrough, the defoaming property was poor.

As described above, according to the method of Comparative Example 1, the sectional shape of the supply path 8 was liable to expand on the second surface side of the silicon substrate 1 by the etching, which was a shape with which the adhesive was liable to be squeezed out into the supply path 8. On the other hand, according to the methods of Examples of the present invention, it was possible to shorten a time during which the silicon on the second surface side of the silicon substrate 1 was exposed to the etchant. Thus, the sectional shape of the supply path 8 was less liable to expand, and it was possible to form the portion substantially in parallel with the second surface as a part of the inner wall of the supply path 8. Therefore, in the bonding, the adhesive was not able to go beyond the portion substantially in parallel with the second surface, and thus, it was possible to manufacture a liquid ejection head having a small interval between the supply paths 8 and having a satisfactory defoaming property.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-107163, filed May 27, 2015, which is hereby incorporated by reference herein in its entirety.

What is claimed is:

1. A liquid ejection head, comprising:
a substrate including a supply path passing through the substrate from a first surface of the substrate to a second surface thereof opposite to the first surface; and
a member bonded to the second surface of the substrate via an adhesive,
wherein an inner wall of the supply path has a portion substantially in parallel with the second surface.

2. A liquid ejection head according to claim 1,
wherein the substrate comprises a plurality of the supply paths, and
wherein an interval between the plurality of supply paths is 1 mm or less.

3. A liquid ejection head according to claim 1,
wherein the inner wall of the supply path has a portion substantially perpendicular to the second surface,
wherein an opening width of the portion of the supply path substantially perpendicular to the second surface is ½ or less of an opening width of the supply path on the second surface, and
wherein the portion substantially perpendicular to the second surface exists in a region that is located within ½ of a thickness of the substrate from the first surface in a substrate thickness direction.

4. A method of processing a silicon substrate, comprising, in the following order, the steps of:
(a) forming an etching mask layer on a second surface of a silicon substrate, the silicon substrate having a (100) crystal plane and having a first surface and the second surface opposite to the first surface;
(b) forming a plurality of blind holes from the second surface side of the silicon substrate;
(c) performing crystal anisotropic etching from the second surface side of the silicon substrate using an etchant to join the plurality of blind holes together;
(d) removing a part of a SiO₂ layer formed on the second surface of the silicon substrate; and
(e) performing crystal anisotropic etching from the second surface side of the silicon substrate using an etchant to form a through hole.

5. A method of processing a silicon substrate according to claim 4,
wherein a plurality of the through holes are formed by the step (a) to the step (e), and
wherein an interval between the plurality of through holes is 1 mm or less.

6. A method of processing a silicon substrate according to claim 4,
wherein the step (b) comprises forming the plurality of blind holes in two or more lines that are symmetrical with respect to a center line in a longitudinal direction of a region in which the plurality of blind holes are to be formed.

7. A method of processing a silicon substrate according to claim 4, wherein the step (b) comprises forming the plurality of blind holes using laser light.

8. A method of processing a silicon substrate according to claim 4, wherein the step (a) comprises forming an opening in a portion of the etching mask layer that is formed in a region in which the plurality of blind holes are to be formed in (b).

9. A method of processing a silicon substrate according to claim 4, wherein the step (b) comprises forming the plurality of blind holes to a depth of 10 μm or more and 125 μm or less from the first surface.

10. A method of processing a silicon substrate according to claim 4, wherein the step (b) comprises forming the plurality of blind holes so that an interval between the plurality of blind holes is 25 μm or more and 115 μm or less.

11. A method of processing a silicon substrate according to claim 4, wherein at least any one of the step (c) or the step (e) comprises using the etchant comprising one of tetramethylammonium hydroxide and potassium hydroxide.

12. A method of processing a silicon substrate according to claim 4, wherein the step (d) comprises removing a part of the SiO₂ layer by one of dry etching and wet etching.
